(19) United States
(12) Patent Application Publication
(10) Pub. No.: US 2006/0180898 A1
(43) Pub. Date: Aug. 17, 2006

(54) Hybrid type semiconductor integrated circuit and method of manufacturing the same

(75) Inventors: Hideyuki Funaki, Tokyo (JP); Kazuhiro Suzuki, Tokyo (JP); Yujiro Naruse, Yokohama-shi (JP); Hiroshi Toshiyoshi, Yokohama (JP); Kazuhiro Takahashi, Tokyo (JP)

Correspondence Address: AMIN & TUROCY, LLP, 1900 EAST 9TH STREET, NATIONAL CITY CENTER, 24TH FLOOR,, CLEVELAND, OH, 44114, US

(73) Assignees: Kabushiki Kaisha Toshiba, Minato-ku (JP); The University of Tokyo, Bunkyo-ku (JP)

(21) Appl. No.: 11/356,413

(22) Filed: Feb. 16, 2006

(30) Foreign Application Priority Data
Feb. 17, 2005 (JP) 2005-041237

(51) Int. Cl. H01L 29/06; H01L 21/30

(52) U.S. Cl. 257/619; 438/459

(57) ABSTRACT

A hybrid type semiconductor integrated circuit includes a semiconductor active region provided in a first area of a substrate; an insulating region surrounding side surfaces of the semiconductor active region; a mechanical electrode provided in a second area adjacent to the first area and surrounded by a part of the insulating region and a trench; and a interconnection layer one end of which is connected to the mechanical electrode and of which the other end extends to the semiconductor active region via a part of the insulating region.

### CROSS REFERENCE TO RELATED APPLICATION

This application is based upon and claims the benefit of priority from the prior Japanese Patent Application No. 2005-041,237 filed on Feb. 17, 2005, the entire contents of which are incorporated herein by reference.

### BACKGROUND OF THE INVENTION

1. Field of the Invention

The present invention relates to a hybrid type semiconductor integrated circuit and a method of manufacturing the same, and more particularly relates to a hybrid type semiconductor integrated circuit in which a micro-electro-mechanical system (called the “MEMS”) is mounted on a substrate, the MEMS being constituted by not only mechanical drive systems such as an actuator and a sensor but also a circuit or an integrated circuit activating the mechanical drive system. Further, the invention relates to a method of manufacturing the foregoing hybrid type semiconductor integrated circuit.

2. Description of the Related Art

Generally, an MEMS manufactured using a semiconductor manufacturing process can assure sophisticated functions and excellent performances. An actuator utilizing an electrostatic attraction force of a lens scanner or the like requires not only a high drive voltage of several ten volts in order to increase a drive distance (displacement output) but also high-voltage wirings. Provided that a high-voltage circuit and an actuator can be constituted as a monolithic integrated circuit, the MEMS will be able to assure an accelerated drive speed and a large displacement output.

The foregoing MEMS includes a high-voltage circuit on a chip and an actuator on another chip. Then, the high-voltage circuit is attached to the actuator as an external unit. Such an MEMS has a complicated configuration since a plurality of high-voltage wirings should be used in order to connect the high-voltage circuit and the actuator. There has been a problem that the operation of the actuator is delayed due to a complicated arrangement of the high-voltage wirings. Further, the high voltage circuit and the actuator are independently manufactured and assembled, which means an increase of a manufacturing cost.

Domestic re-publication of PCT international application No. 2002-534,285 discloses an MEMS in which an amplifier (or an integrated circuit) and a resonator (or an actuator) are mounted on one substrate. In the MEMS, the amplifier is constituted by a transistor provided on a front surface of the substrate. The resonator is made of a polycrystalline silicon germanium (SiGe) film which is positioned over the transistor and a transistor wiring. Both of the amplifier and the actuator are monolithically integrated on one substrate, so that the foregoing MEMS assures excellent characteristic features.

The following problems are conceivable in the foregoing MEMS of the cited reference.

(1) The polycrystalline silicon germanium film which constitutes the resonator and is stacked over the amplifier should be several μm thick in order to strengthen the resonator. Further, the foregoing film should be several ten μm thick depending upon a kind of the actuator when the resonator has to be mechanically strong.

(2) The thicker the polycrystalline silicon germanium film, the longer it takes to make the film.

(3) The resonator is made after the transistor for making the amplifier is manufactured and the transistor wiring is completed. Since the transistor wiring is made of an aluminum alloy film having a low resistance, the resonator has to be made of a material which can be formed at a low temperature.

(4) The number of MEMS manufacturing processes should be increased because of a process for making the polycrystalline silicon germanium film.

(5) The polycrystalline silicon germanium film made by a low temperature process has a relatively high resistance compared with the transistor wiring. Further, the operation of the resonator is delayed due to the wiring-delay of the wiring between the resonator and the amplifier.

### BRIEF SUMMARY OF THE INVENTION

The present invention has been contemplated in order to overcome the problems of the related art, and is intended to provide a hybrid type semiconductor integrated circuit including a simple MEMS in which a mechanical system and an electrical system are mounted on the same one substrate (on the common substrate).

A further object of the invention is to provide a method of manufacturing a hybrid type semiconductor integrated circuit including an MEMS. In the method, an electrical drive system is made and wired, and then a mechanical drive system is easily made without using a high-temperature process.

According to a first aspect of the embodiment, there is provided a hybrid type semiconductor integrated circuit which includes a semiconductor active region provided in a first area of a substrate; an insulating region surrounding side surfaces of the semiconductor active region; a mechanical electrode provided in a second area adjacent to the first area and surrounded by a part of the insulating region and a trench; and an interconnection layer one end of which is connected to the mechanical electrode and the other end of which extends to the semiconductor active region via a part of the insulating region.

In accordance with a second aspect of the embodiment, there is provided a hybrid type semiconductor integrated circuit which includes a first semiconductor active region provided in a first area of a substrate and including a semiconductor element; a second semiconductor active region provided in a second area adjacent to the first area; an insulating region surrounding side surfaces of the first and second semiconductor active regions; a mechanical electrode provided in a third area adjacent to the second area and surrounded not only by a part of the insulating region extending on the side surface of the second area but also by a trench; a first interconnection layer one end of which is connected to the second semiconductor active region and of which the other end extends to the first semiconductor active region; and a second interconnection layer one end which of is connected to the mechanical electrode and of which the other end extends to the one end of the first interconnection layer on the second semiconductor active region via a part of the insulating region.

According to a third aspect of the embodiment, there is provided a method of manufacturing a hybrid type semiconductor integrated circuit. The method includes forming an insulating region on a semiconductor layer of a substrate in accordance with a profile of a first area, and forming a semiconductor active region, the semiconductor active region being surrounded by the insulating region; forming an interconnection layer, the interconnection layer passing over a part of the insulating region and extending from the semiconductor active region to a part of a second area adjacent to the first area of the semiconductor layer; forming a trench, in the second area, around the semiconductor layer to which the interconnection layer is connected and a part of the insulating region; and forming a mechanical electrode whose side surfaces are surrounded by the trench and a part of the insulating region.

In accordance to a final aspect of the embodiment, there is provided a method of manufacturing a hybrid type semiconductor integrated circuit. The method includes forming an insulating region on a semiconductor layer of a substrate in accordance with profiles of adjacent first and second areas, and forming a first semiconductor active region in the first area and a second semiconductor active region in the second area, the first and second semiconductor active regions being surrounded by the insulating region; forming a first interconnection layer one end of which is positioned in the second semiconductor active region and of which the other end extends to the first semiconductor active region; forming a second interconnection layer, one end of which is connected to the first interconnection layer and the other end of which extends from the second semiconductor active region, passes over a part of the insulating region, and is connected to a part of a third area adjacent to the second area of the semiconductor layer; and forming a trench, in the second area, around the semiconductor layer to which the interconnection layer is connected and a part of the insulating region, and forming a mechanical electrode whose side surfaces are surrounded by the trench and a part of the insulating region.

### BRIEF DESCRIPTION OF THE DRAWINGS

FIG. 1 is a cross section of a hybrid type semiconductor integrated circuit according to one embodiment of the invention, taken along line F1-F1 in FIG. 2;

FIG. 2 is a top plan view of the hybrid type semiconductor integrated circuit of FIG. 1;

FIG. 3 shows a system configuration of the hybrid type semiconductor integrated circuit of FIG. 1 and FIG. 2;

FIG. 4 is a diagram of a drive circuit in the hybrid type semiconductor integrated circuit of FIG. 1 and FIG. 2;

FIG. 5 is a diagram of a test circuit in the hybrid type semiconductor integrated circuit of FIG. 1 and FIG. 2;

FIG. 6 is a cross section of the hybrid type semiconductor integrated circuit of FIG. 1 and FIG. 2 in a first manufacturing process;

FIG. 7 is a cross section of the hybrid type semiconductor integrated circuit in a second manufacturing process;

FIG. 8 is a cross section of the hybrid type semiconductor integrated circuit in a third manufacturing process;

FIG. 9 is a cross section the hybrid type semiconductor integrated circuit in a fourth manufacturing process;

FIG. 10 is a cross section of the hybrid type semiconductor integrated circuit in a fifth manufacturing process;

FIG. 11 is a cross section of the hybrid type semiconductor integrated circuit in a sixth manufacturing process;

FIG. 12 is a cross section of the hybrid type semiconductor integrated circuit in a seventh manufacturing process;

FIG. 13 is a cross section of the hybrid type semiconductor integrated circuit in an eighth manufacturing process;

FIG. 14 is a cross section of the hybrid type semiconductor integrated circuit in a ninth manufacturing process; and

FIG. 15 is a cross section of the hybrid type semiconductor integrated circuit in a tenth manufacturing process.

### DETAILED DESCRIPTION OF THE INVENTION

[Device Structure of Hybrid Type Semiconductor Integrated Circuit]

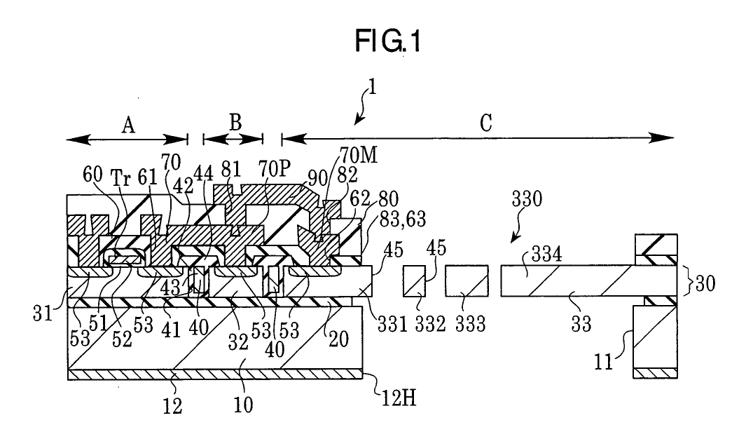

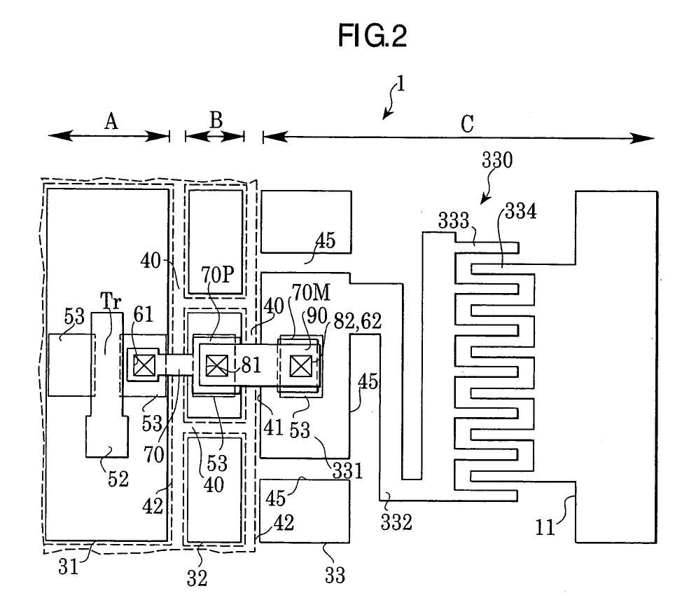

Referring to FIG. 1 and FIG. 2, a hybrid type semiconductor integrated circuit 1 (called the “semiconductor integrated circuit 1” hereinafter) includes a first semiconductor active region 31; a second semiconductor active region 32; an insulating region 40; a mechanical electrode 331; a first interconnection layer (thin film wiring) 70; and a second interconnection layer (thin film wiring) 90, all of which are mounted on a substrate 10. The first semiconductor active region 31 is arranged in a first area A of the substrate 10 (shown at the left sides in FIG. 1 and FIG. 2), and includes a semiconductor element Tr. The second semiconductor active region 32 is arranged in a second area B (shown at the center of FIG. 1 and FIG. 2) adjacent to the first area A. The insulating region 40 surrounds side surfaces of the first and second semiconductor active regions 31 and 32. The mechanical electrode 331 is positioned in a third area C (shown at the right sides in FIG. 1 and FIG. 2), and has a side surface thereof surrounded by a part of the insulating region 40 and a trench 45. The first interconnection layer 70 has its one end (called the “first end”) in the second semiconductor active region 32, and has the other end (called the “second end”) thereof extending toward the first semiconductor active region 31. The second interconnection layer 90 has one end (called the “first end”) connected to the mechanical electrode 331 and the other end (called the “second end”) thereof, passing over a part of the insulated region 40 and connected to the first interconnection layer 70.

The substrate 10 is made of a semiconductor substrate, specifically, a mono-crystal silicon substrate. A mono-crystal semiconductor layer 30 is stacked on the substrate 10 via an insulating layer 20. The mono-crystal semiconductor layer 30 is preferably a mono-crystal silicon layer. In the semiconductor integrated circuit 1, an SOI (silicon on insulator) substrate is used. Alternatively, an SOS (silicon on sapphire) substrate is usable in which the mono-crystal semiconductor layer 30 may be stacked on a sapphire substrate or the like. Further, the mono-crystal semiconductor layer 30 may be replaced by a compound semiconductor layer. Still further, the mono-crystal semiconductor layer 30 may be replaced by either a poly-crystalline semiconductor layer or a non-crystalline semiconductor layer.

A backside metal film 12 is laid on the rear surface of the substrate 10 except the third area C where a mechanical drive system 330 is provided. The backside metal film 12 is used as a backside electrode or an etching mask, for instance. The mechanical drive system 330 constitutes the MEMS.

The first area A of the substrate 10 houses an integrated circuit such as a drive circuit producing control signals for the mechanical drive system 330, and a test circuit checking the operation of the drive circuit, both of which function as an electrical drive system of the MEMS. The mono-crystal semiconductor layer 30 extends all over the substrate 10. The first semiconductor active region 31 is constituted by a part of the mono-crystal semiconductor layer 30, i.e., the first semiconductor active region 31 is made of the material same as that of the mono-crystal semiconductor layer 30, and is as thick as the mono-crystal semiconductor layer 30.

The insulating region 40 includes an insulating trench 41, a first insulator 42, an embedded layer 43, and a second insulator 44. The insulating trench 41 extends through the mono-crystal semiconductor layer 30. The first insulator 42 is positioned in the insulating trench 41. The embedded layer 43 is surrounded by the first insulator 42 and is buried in the insulating trench 41. The second insulator 44 is positioned over the insulating trench 41. The insulating trench 41 has a small diameter, and is deep enough to reliably insulate the transistor element Tr, which is effective reducing an area occupied by the insulating region 40. The first and second insulators 42 and 44 are preferably made of silicon oxide films. The embedded layer 43 is preferably made of a poly-crystalline silicon film. The insulating region 40 may be made of a field insulator (LOCOS) which is produced by selectively oxidizing the surface of the mono-crystal semiconductor layer 30. In such a case, the insulating trench 41 is dispensable.

The transistor element Tr constituting the electrical drive system is an insulated gate field effect transistor (IGFET). In this specification, it is assumed that the term IGFET includes MOSFET (Metal Oxide Semiconductor Field Effect Transistor) and MISFET (Metal Insulator Semiconductor Field Effect Transistor).

The IGFET is positioned in the first semiconductor active region 31, and has a channel region, an insulated gate film 51 on the channel region, a control electrode (gate electrode) 52 on the insulated gate film 51, and a pair of main electrodes (a source region and a drain region) 53 which are positioned on a main surface of the first semiconductor active region 31 at the opposite sides of the control electrode 52. The channel region is provided in the surface of the first semiconductor active region 31 under the control electrode 52. Although a channel conductivity type of the IGFET is not shown, the semiconductor integrated circuit 1 includes a complementary IGFET. An n-channel conductivity type IGFET is provided on the p-type semiconductor active region 31 while a p-channel conductivity type IGFET is provided on the n-type semiconductor active region 31.

The insulated gate film 51 is preferably made of a single layer of a silicon oxide film or a silicon nitride film, or a complex layer of the silicon oxide film and silicon nitride film. The control electrode 52 is preferably made of either a single layer or a complex layer of a polycrystalline silicon film and a refractory metal film or a refractory metal silicide film. An interlayer dielectric 60 is provided on the semiconductor element Tr. The first interconnection layer 70 is laid on the interlayer dielectric 60. The interlayer dielectric 60 is preferably made of a single layer of a silicon oxide film, a silicon nitride film, a phospho silicate glass film (PSG) or a phosphate boron silicate glass film (BPSG), or a complex layer of any of foregoing films. The first end of the first interconnection layer 70 passes through a connection hole 61 on the main electrode 53, and is electrically connected to the main electrode 53. The first interconnection layer 70 is preferably made of a single layer of an aluminum film, an aluminum alloy film or a copper film, or a complex layer of any of the foregoing films together with a barrier metal film or anti-reflecting film. The term “aluminum alloy film” refers to an aluminum film to which Si, Cu and so on are added. If the circuit configuration is complicated, the first interconnection layer 70 may be crosses. In such a case, it is conceivable the interconnection layer 70 may have two or more thin films (a multi-layer thin film wiring layer).

A bi-polar transistor may be usable as the semiconductor element Tr. Further, a complementary IGFET and a bi-polar transistor may be used together. Needless to say, the transistor element Tr includes a resistance element and a capacitance element.

An external test terminal (test pad) 70P is provided on the second area B of the substrate 10, and is connected to the test circuit. The second area B is put between the first area A and the third area C. The second semiconductor active region 32 is constituted by a part of the monocrystal semiconductor layer 30 similarly to the first semiconductor active region 31. The operation of the drive circuit of the semiconductor integrated circuit 1 is usually tested in the manufacturing process. The test may be omitted on the case-by-case basis. However, since specifications of a mechanical drive system or an electric drive system of an MEMS for application specific integrated circuits (ASIC) may be frequently changed, operation tests are indispensable, so that the second area B of the semiconductor integrated circuit 1 should be preferably provided.

The insulating region 40 is structured similarly to the insulating region 40 for the first semiconductor active region 31, and includes the insulating trench 41, the first insulator 42, the embedded layer 43 and the second insulator 44.

The second semiconductor active region 32 is provided with a semiconductor region 53 on a surface thereof. The second end of the first interconnection layer 70 is electrically connected to the semiconductor region 53. This semiconductor region 53 is similar to the main electrode 53 of the semiconductor element Tr. The semiconductor region 53 may have the conductivity same as or reverse to that of the second semiconductor active region 32 depending upon an application. The second end of the first interconnection layer 70 is designed to have a large flat area compared to the connecting hole 61 in order to assure manufacturing alignment allowance or to enable easy contacting of an inspection probe. In this embodiment, the second end of the first interconnection layer 70 is not always required to be connected to the semiconductor region 53 on the second semiconductor active region 32 but may be provided only on the interlayer dielectric 60 on the second semiconductor active region 32.

The mechanical drive system 330 is provided in the third area C of the substrate 10. The mechanical electrode 331 is a part of the mechanical drive system 330, and is housed therein. The mechanical drive system 330 is substantially flush with the electrical drive system on the semiconductor integrated circuit 1. In other words, the mechanical drive system 330 and the mechanical electrode 331 are in the third area C which is adjacent to the second area B. Further, the mechanical drive system 330 and the mechanical electrode 331 are made of a part of the mono-crystal semiconductor layer 30 which constitutes the first semiconductor active region 31. The monocrystal semiconductor layer 30 is several μm to several ten μm thick, is made of the mono-crystal silicon as described above, for example, and is strong enough to support the mechanical drive system 330.

A cavity 11 is formed on the third area C except the area where the mechanical electrode 331 is positioned, i.e., the cavity 11 is located where the mechanical drive system 330 is provided. In short, a part of the substrate 10 and a part of an insulating layer 20 are cut off, so that the rear surface of the mono-crystal semiconductor layer 30 is exposed.

The mechanical drive system 330 is a lens scanner which is activated by an electrostatic attraction force, and includes the mechanical electrode 331, a deformer 332 in the shape of a flat crank, a movable part 333 in the shape of a comb, and a stationary part 334 (not shown) in the shape of a comb and adapted to be engaged with the movable part 333. The mechanical electrode 331 receives a high-voltage drive signal from the drive circuit of the electrical drive system. The stationary part 334 is connected to a reference power source (having a grounding potential), and receives reference power. When the drive signal is supplied to the mechanical electrode 331, an electrostatic attraction force is produced between the movable and stationary parts 333 and 334, and elastically deforms the deformer 332, thereby attracting the movable part 333 toward the stationary part 334.

In the mechanical drive system 330, the mechanical electrode 331, deformer 332, movable part 333 and stationary part 334 have a single piece structure but are partly separated by a trench 45 extending through the mono-crystal semiconductor layer 30. In short, the trench 45 defines the deformer 332, and the movable and stationary parts 333 and 334. The trench 45 remains hollow, and differs from the insulating trench 41 for the insulating region 40 in this respect. The trench 45 should have a mechanically movable part. Alternatively, the mechanical drive system 330 may be structured to supply the drive signal to the stationary part 334, and the reference power to the movable part 333.

The mechanical electrode 331 is defined by the trench 45 and a part of the insulating region 40, and is adjacent to the second semiconductor active region 32. The insulating region 40 extends over the side surfaces of the second semiconductor active region 32. In short, the trench 45 is in communication with the insulating trench 41.

The semiconductor region 53 which is similar to the main electrode 53 of the transistor Tr is located on the mechanical electrode 331. The semiconductor region 53 has the conductivity same as that of the mono-crystal semiconductor layer 30 of the mechanical electrode 331, and has a large concentration of impurities in order to reduce contact resistance and to prevent alloy spike, and so on. The second end of the second interconnection layer 90 whose first end is connected to the second end (external inspecting terminal 70P) of the first interconnection layer 70 is electrically connected to the semiconductor region 53 of the mechanical electrode 331. The second interconnection layer 90 is provided over the first interconnection layer 70 via the interlayer dielectric 80. The first end of the second interconnection layer 90 is connected to the first interconnection layer 70 via the connection hole 81 of the interlayer dielectric 80. Further, the second end of the second interconnection layer 90 is connected to the semiconductor region 53 of the mechanical electrode 331 via the first interconnection layer 70M on the mechanical electrode 331. Still further, the second end of the second interconnection layer 90 and the first interconnection layer 70M are electrically connected via a connection hole 82 in the interlayer dielectric 80. The second interconnection layer 90 may be made of the material same as that of the first interconnection layer 70. In such a case, the second interconnection layer 90 may be used as a part of a multi-layer wiring constituted by the first interconnection layer 70.

In the semiconductor integrated circuit 1, the mechanical drive system 330, e.g., the lens scanner which is an actuator, is not stacked directly on (or over) the electrical drive system. The mechanical drive system 330 is provided in the third area C which is flush with the first area A, and is constituted by the mono-crystal semiconductor layer 30 by adopting the SOI substrate (or SOS substrate).

The side surfaces of the mono-crystal semiconductor layer 30 (which constitutes the mechanical electrode 331 of the mechanical drive system 330) are surrounded by the trench 45 and a part of the insulating region 40. Further, the second interconnection layer 90 passes over a part of the insulating region 40, and electrically connects the mechanical electrode 331 and the drive circuit. The trench 45 defining the deformer 332 and the movable and stationary parts 332 and 334 of the mechanical drive system 330 is formed after completing the integrated circuit and interconnection layers as will be described later. However, when the mechanical electrode 331 has its entire surfaces surrounded by the trench 45, the interconnection layers may be broken (cut off). In order to overcome this problem, if a part of the insulating region 40 (which insulates the semiconductor element Tr) is left as it is between the second semiconductor active region 32 of the third area C (or the first semiconductor active region 31 of the first area A) and the mechanical electrode 331, it is not necessary to form the trench 45 for the mechanical drive system 330. The second interconnection layer 90 can be laid on the insulating region 40. In short, the interconnection layer process may be applied to the mechanical electrode 331, and the second interconnection layer 90 will not be cut on the insulating region 40.

Alternatively, the integrated circuit and the mechanical electrode 331 may be electrically connected using a bonding wire. However, an optical MEMS device which has to interact with an external unit has the following problem. If the bonding wire is laid in a complicated pattern in such a device, an optical path may be three-dimensionally affected. Further, with a device which drives a magnetic head of a hard disc drive (HDD) using an actuator, a chip-size is too small, i.e. 0.33 mm×0.9 mm, so that it is very difficult to bond or lay the bonding wire.

[System Configuration of the Hybrid Type Semiconductor Integrated Circuit]

Referring to FIG. 3, the semiconductor integrated circuit 1 includes a drive circuit 100 in the first area A, a test circuit 200, an external test terminal 70P, and a mechanical drive system 330. The test circuit 200 is in the second area B and is connected to the drive circuit 100. The external test terminal 70P is in the second area B and is connected to the test circuit 200. The mechanical drive system 330 is in the third area C.

The external test terminal 70P is constituted by the second end of the first interconnection layer 70. The mechanical drive system 330 includes the mechanical electrode 331, which is connected to an output terminal of the drive circuit 100 via the external test terminal 70P and test circuit 200.

The second area B is basically free from the semiconductor element Tr and is an independent island. Therefore, even if the external test terminal 70P, the second semiconductor active region 32 and so on are damaged by a stress caused by the test probe brought into contact with the external test terminal 70P, the first semiconductor active region 31 will not be affected. Therefore, the semiconductor integrated circuit 1 will not become defective. In short, the second area B functions as a buffer for external stresses.

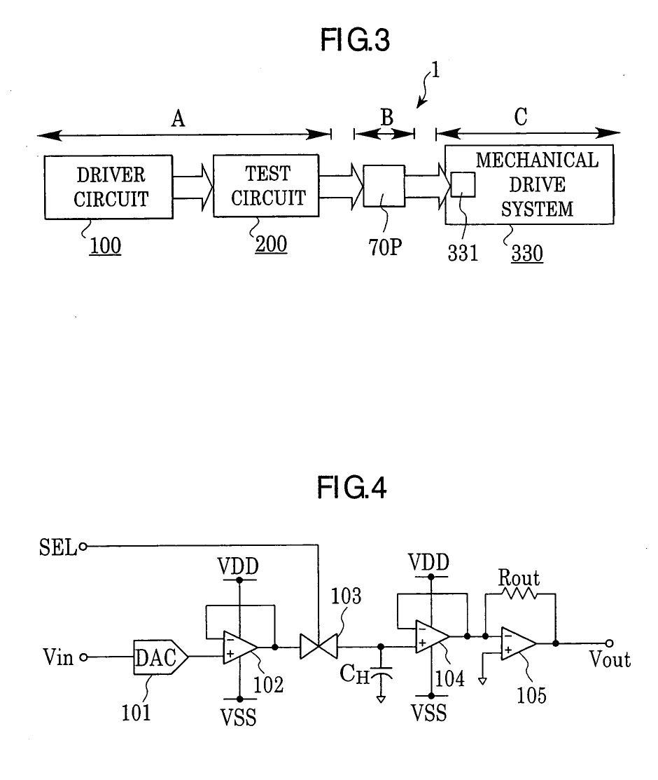

As shown in FIG. 4, the drive circuit 100 includes a digital-to-analog converter (DAC) 101, an input voltage holding amplifier 102, an analog switch 103, a holding amplifier 104, and an output amplifier 105. The drive circuit 100 analogously controls the mechanical drive system 300. Alternatively, the drive circuit 100 may digitally control the mechanical drive system 300 by employing the PWM.

The test circuit 200 includes inverters 201 and 202, and analog switches 203 and 204. Refer to FIG. 5. In the manufacturing process of the semiconductor integrated circuit 1, when the mechanical drive system 300 is not manufactured after the test circuit 200 is completed, the monocrystal semiconductor layer 30 in the third area C remains unsoiled, and outputs of the inverters 201 and 202 are short-circuited. In this state, the analog switch 203 is inserted between the inverter 201 and the actuator 331, and the analog switch 204 is inserted between the inverter 202 and the actuator 331. Therefore, the operation of the drive circuit 100 can be independently tested via their associated channels.

[Method of Manufacturing Hybrid Type Semiconductor Integrated Circuit]

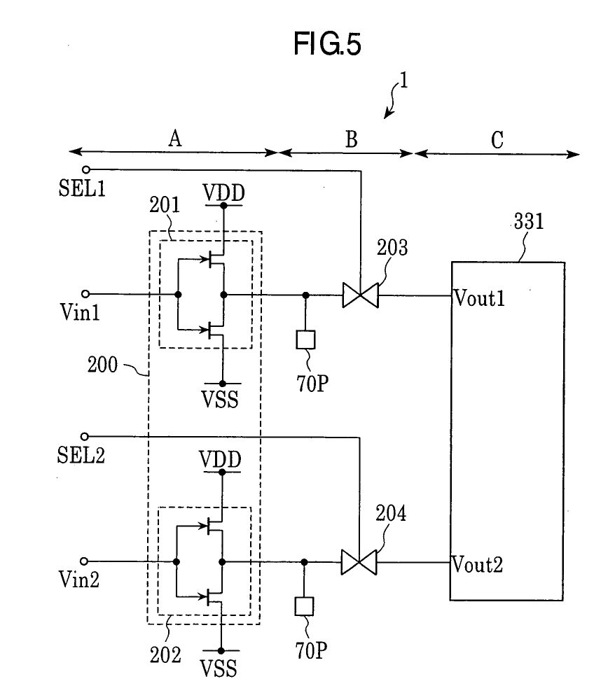

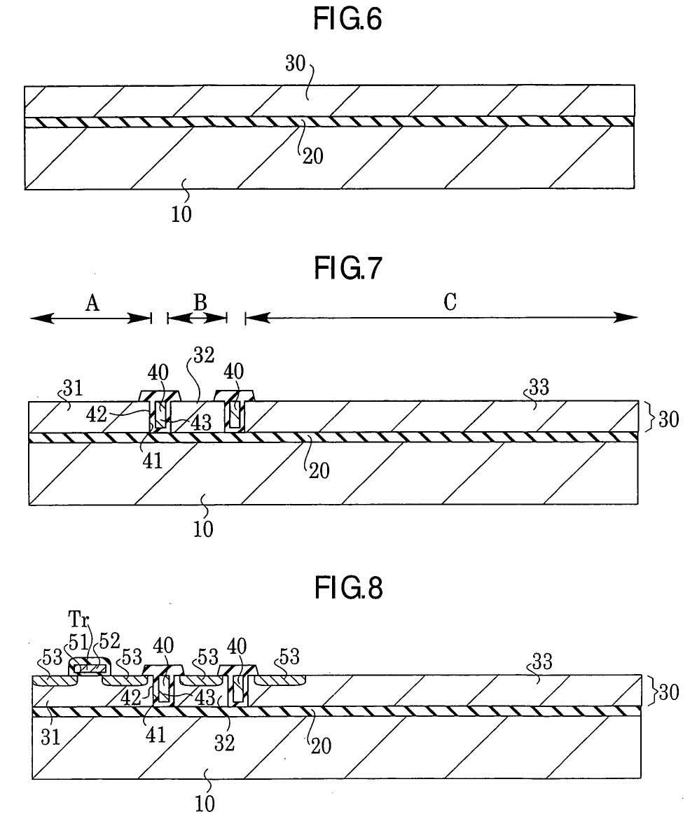

The semiconductor integrated circuit 1 will be manufactured as described hereinafter. First of all, the SOI substrate is prepared as follows. Refer to FIG. 6.

(1) The insulating layer 20 is formed on the substrate 10, and the mono-crystal semiconductor layer 30 is formed on the insulating layer 20.

(2) Impurities are injected into a bulk of the substrate 10, thereby completing the insulating layer 20. An upper part of the substrate 10 is used as the monocrystal semiconductor layer 30.

(3) The mono-crystal layer 30 is pasted onto the insulating layer 20.

As shown in FIG. 7, the insulating region 40 is formed on the mono-crystal semiconductor layer 30 in the first and second areas A and B of the substrate 10. Thereafter, the first and second semiconductor active regions 31 and 32 whose side surfaces are surrounded by the insulating region 40 in the first and second areas A and B will be simultaneously made using the mono-crystal semiconductor layer 30. The first, second and third areas A, B and C are defined by the insulating region 40.

The insulating region 40 is made as follows. First of all, the surface of the mono-crystal semiconductor layer 30 is dry-etched in order to form the insulating trench 41, which extends to the insulating layer 20 from the mono-crystal semiconductor layer 30. Next, the first insulator 42 is made on the bottom and side surfaces of the insulating trench 41. The embedded layer 43 is made in the insulating trench 41 via the first insulator 42. Thereafter, the second insulator 44 is formed on the embedded layer 43, so that the insulating region 40 is completed.

Referring to FIG. 8, the semiconductor element Tr is formed on the semiconductor active region 31 of the first area A as described hereinafter. First of all, the insulated gate film 51 is formed on the first semiconductor active region 31. The control electrode 52 is made on the insulated gate film 52. A pair of main electrodes 53 are formed on the first semiconductor active region 31, and are positioned at the opposite sides of the control electrode 52. At the same time, another semiconductor region 53 is formed on the second area B, and still another semiconductor region 53 is also formed on the mechanical electrode 331 in the third area C.

The interlayer dielectric 60 is formed on the semiconductor element Tr. Then, the connection hole 61 is made in the interlayer dielectric 60. The connection hole 61 extends from the pair of main electrodes 53 of the semiconductor element Tr to the semiconductor region 53 in the second area B. Further, the connection hole 62 is simultaneously made in the interlayer dielectric 60 on the semiconductor region 53.

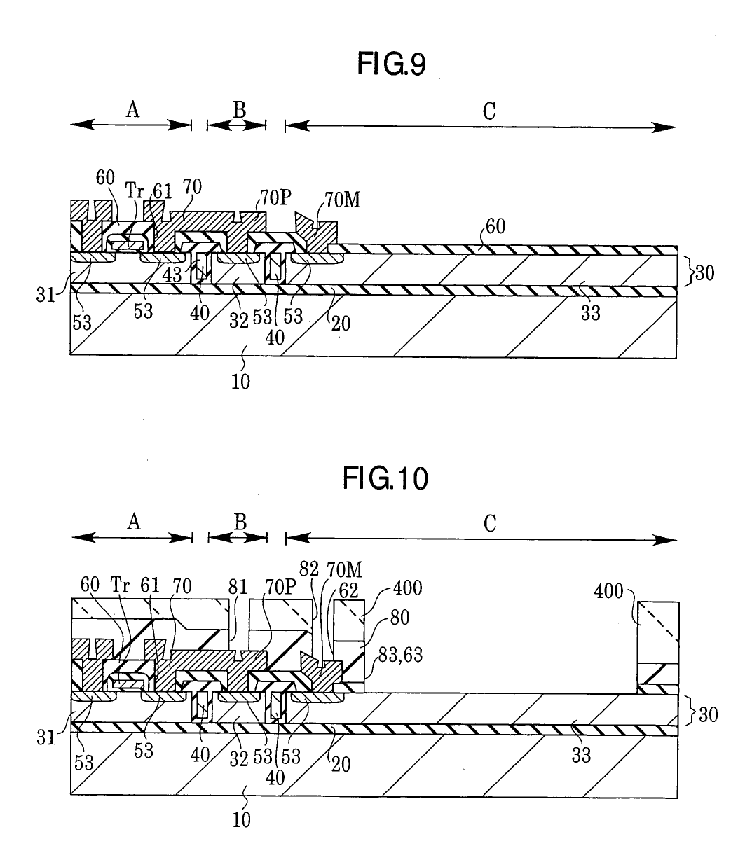

Thereafter, the first interconnection layer 70 is formed on the interlayer dielectric 60 as shown in FIG. 9. The first interconnection layer 70 has its one end (called the “first end”) connected to the main electrodes 53 via the connection hole 61, and the other end (called the “second end”) thereof connected to the semiconductor region 53 via the connection hole 61. The second end of the first interconnection layer 70 is also used as the external test terminal 70P. At the same time, the first interconnection layer 70M is formed on the interlayer dielectric 60. The first interconnection layer 70M is connected to the semiconductor region 53 via the connection hole 62, and serves as an intermediate wiring between the second interconnection layer 90 and the mechanical electrode 331 in order to prevent break, malfunction or the like of the second interconnection layer 90. The first interconnection layers 70 and 70M are made by patterning aluminum alloy films, which are prepared by the sputtering process, using the photolithography and etching techniques.

In this state, the integrated circuit and interconnection layers are completed. Specifically, the drive circuit 100 and the test circuit 200 are completed, and the first interconnection layer 70 connecting the semiconductor elements Tr is put in position. Further, the external test terminal 70P is completed. The operation of the drive circuit 100 can be checked by bringing a test probe into contact with the external test terminal 70P.

The interlayer dielectric 80 is made on the first interconnection layers 70 and 70M. An etching mask 400 is formed on the interlayer dielectric 80 (refer to FIG. 10), and opens on the external test terminal 70P, first interconnection layer 70M (connected to the mechanical electrode 331), and deformer 332 and movable and stationary parts 333 and 334 (of the mechanical drive system 330). The mask 400 is preferably a positive type photoresist mask.

An exposed part of the interlayer dielectric 80 is etched and removed using the etching mask 400. A connection hole 81 is made in the interlayer dielectric 80 on the external test terminal 70P while a connection hole 82 is made in the interlayer dielectric 80 on the mechanical electrode 331. In the same manufacturing process, an opening 83 is made on the movable part 333 of the mechanical drive system 330, and an opening 63 is made in interlayer dielectric 80. Thereafter, the etching mask 400 is removed.

Referring to FIG. 11, the second interconnection layer 90 is formed on the interlayer dielectric 80. The second interconnection layer 90 has its one end (called the “first end”) connected to the external test terminal 70P via the connection hole 81 and the other end thereof (called the “second end”) connected to the first interconnection layer 70M via the connection hole 82. The second interconnection layer 90 further extends to the semiconductor region 53 of the mechanical electrode 331 via the first interconnection layer 70. The second interconnection layer 90 is made similarly to the first interconnection layers 70 and 70M, e.g., by patterning aluminum alloy films, which are prepared by the sputtering process, using the photolithography and etching techniques.

Further, the rear metal film 12 is formed on the rear surface of the substrate 10 as shown in FIG. 11. The rear metal film 12 is an aluminum film prepared by the vacuum evaporation process, and is used mainly as an etching mask. So long as the substrate 10 is relatively thin, a photoresist mask may be used in place of the rear metal film 12.

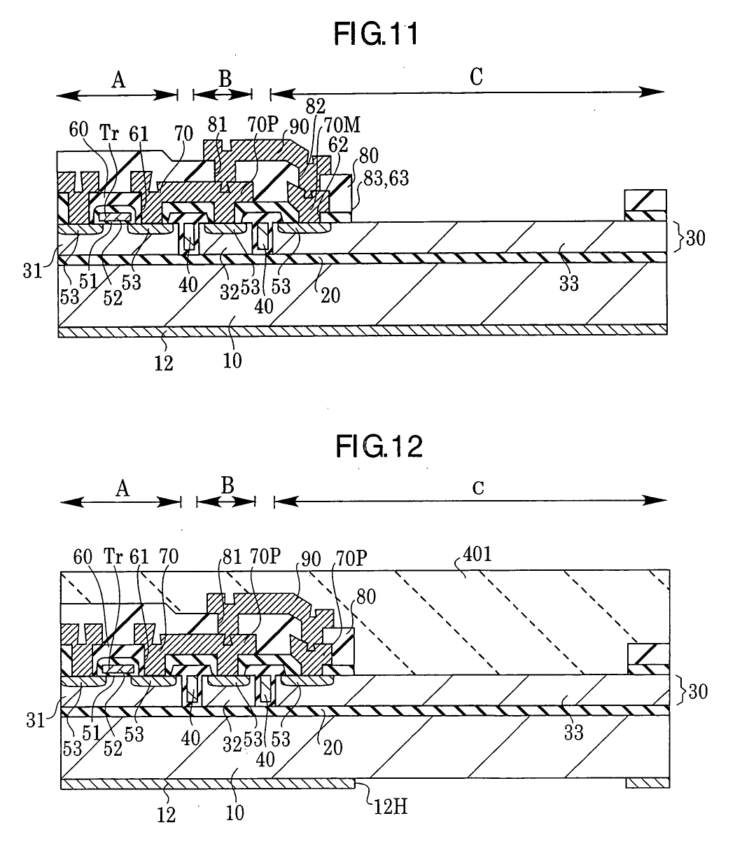

A protection mask 401 is made on the substrate 10 in order to protect the second interconnection layer 90 and areas where the mechanical drive system 330 and so on are formed. The protection mask 401 is preferably a positive photoresist mask. Referring to FIG. 12, the rear metal film 12 is partly removed from the area where the deformer 332, movable part 333 and stationary part 334 of the mechanical drive system 330 are formed. An opening 12H is made in the rear metal film 12. Thereafter, the protection mask 401 is removed.

A further protection mask 402 is formed in order to cover the rear surface of the substrate 10 exposed via the opening 12H of the rear metal film 12. The protection mask 402 is preferably a positive photoresist film. An etching mask 410 is made in order to form the mechanical drive system 330 on the substrate 10. The etching mask 410 opens in accordance with profiles of the mechanical electrode 331, deformer 332, movable part 333 and stationary part 334, and is preferably a negative photoresist film.

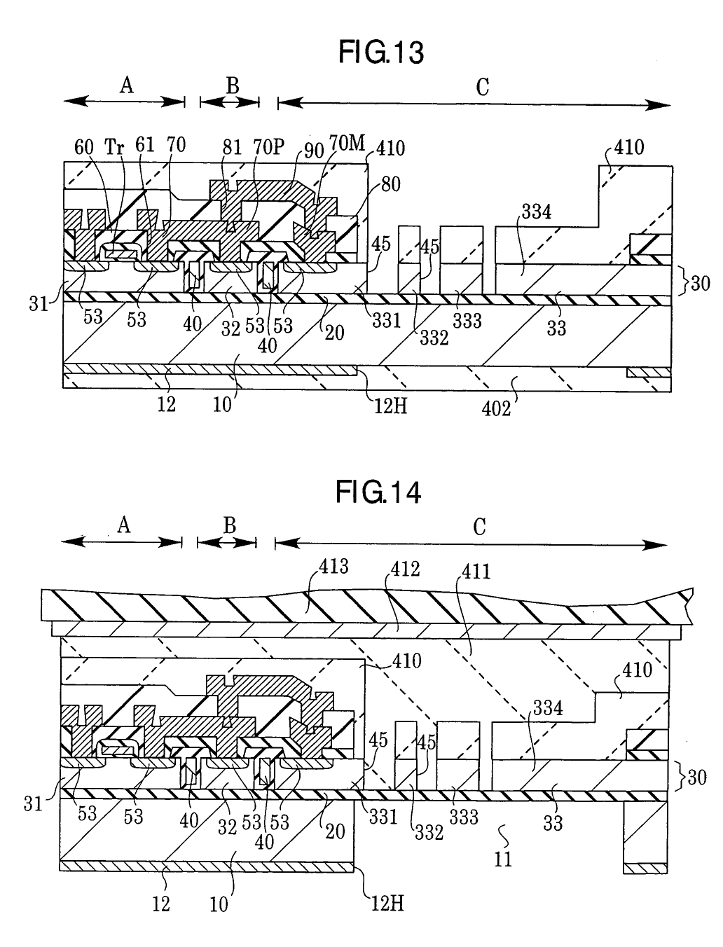

Referring to FIG. 13, the etching mask 410 is used to remove the monocrystal semiconductor layer 30 (exposed via the opening of the etching mask 410) from the surface thereof to the insulating layer 20, thereby forming the trench 45. The ansotropic etching such as the reactive ion etching (RIE) is adopted for this purpose. The trench 45 defines the mechanical electrode 331, the deformer 332, the movable part 333 and the stationary part 334.

The etching mask 410 is left as it is. A photoresist mask 411 is formed on the etching mask 410 all over the substrate 10. The photoresist mask 411 is then flattened (refer to FIG. 14). The photoresist mask 411 is preferably a positive photoresist film. Thereafter, a support substrate 413 is formed on the photoresist mask 411 (on the substrate 10) via catching grease 412.

As shown in FIG. 14, the rear metal film 12 is used as an etching mask in order to remove a part of the substrate 10 exposed via the opening 12H (the exposed part corresponding to the third area C) from the rear surface thereof to the insulating layer 20, thereby making the cavity 11. The anisotropic etching such as RIE is utilized for the foregoing purpose. A sufficient etching ratio can be assured for the substrate 10, so that the insulating layer 20 can serve as an etching stop when making the cavity 11.

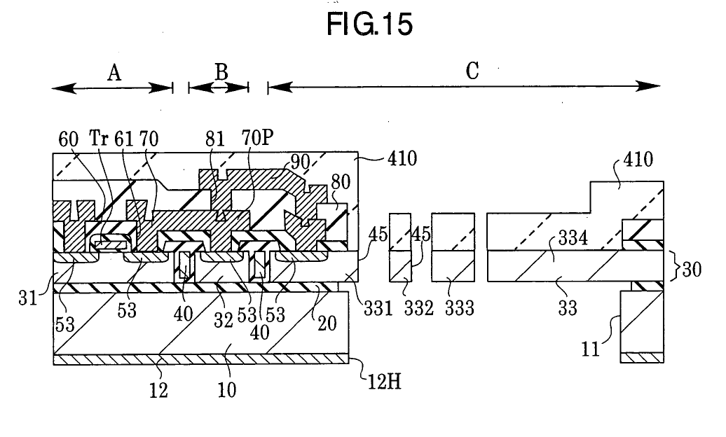

Thereafter, the support substrate 413 and photoresist film 412 are removed, so that the etching mask 410 having the trench 45 is again exposed. The insulating layer 20 is removed from the front and rear surfaces of the substrate 10 via the etching mask 410 and via the opening 12H of the rear metal film 12. Refer to FIG. 15. The insulating layer 20 is preferably removed by the wet etching process. The semiconductor integrated circuit 1 is completed.

As described so far, in the semiconductor integrated circuit 1, the mechanical electrode 331 is surrounded by the trench 45, which defines a part of the insulating region 40 surrounding the first and second semiconductor active regions 31 and 32 where integrated circuit (i.e., the drive circuit 100 and test circuit 200) is mounted. Therefore, the second interconnection layer 90 connecting the integrated circuit and the mechanical electrode 331 can be arranged above a part of the insulating region 40. In the foregoing manufacturing process, the interconnection layer process can be applied to an area above the mechanical electrode 331. When the interconnection layer process is finished, the integrated circuit and the mechanical drive system 300 can be electrically connected.

So long as the integrated circuit is manufactured according to a predetermined specification, the mechanical drive system 330 can be made to have a variety of functions for desired purposes. It is therefore possible to extensively shorten a time period for completing the semiconductor integrated circuit 1. This is because only a time for making the mechanical drive system 300 is added. Therefore, the semiconductor integrated circuit 1 and the method of manufacturing the same will be effectively applied to application specific integrated circuits.

With the semiconductor integrated circuit 1, the test circuit 200 is mounted in the first area A while the external test terminal 70P is mounted in the second area B. This enables the operation test of the drive circuit 100 to be executed during the manufacturing process. It is also possible to improve the electrical reliability and yield ratio of the semiconductor integrated circuit 1.

The present invention is applicable to not only the foregoing embodiment but also to a variety of hybrid type semiconductor integrated circuits in which MEMSs (i.e., not only electric drive systems such as electric circuits, integrated circuits and so on but also mechanical drive systems such as actuators, sensors and so on) are mounted on chips in fields of optical switch MEMSs, bio-MEMS, displays, meters and so on.

The present invention can provide the hybrid type semiconductor integrated circuit in which the MEMSs (the mechanical drive system and the electrical drive system) are mounted flush on the same chip.

Further, once the electrical drive system is completed and wired, the mechanical drive system can be easily manufactured without using a high temperature process.

What is claimed is:

1. A hybrid type semiconductor integrated circuit comprising:
a semiconductor active region provided in a first area of a substrate;
an insulating region surrounding side surfaces of the semiconductor active region;
a mechanical electrode provided in a second area of the substrate adjacent to the first area and surrounded by a part of the insulating region and a trench; and
an interconnection layer one end of which is connected to the mechanical electrode and the other end of which extends to the semiconductor active region via a part of the insulating region.

2. The integrated circuit of claim 1, wherein the insulating region includes an insulating trench and an insulator buried in the insulating trench.

3. The integrated circuit of claim 1, wherein the insulating region is a selective oxide film on the semiconductor active region.

4. The integrated circuit of claim 1, wherein the substrate is a semiconductor substrate or an insulating substrate; and the semiconductor active region is a mono-crystal semiconductor layer provided on the substrate via the insulator.

5. The integrated circuit of claim 1, further comprising:
a mechanical drive system provided in the second area and operated in response to a drive signal applied to the mechanical electrode; and
a drive circuit provided in the first area and generating the drive signal.

6. A hybrid type semiconductor integrated circuit comprising:
a first semiconductor active region provided in a first area of a substrate and including a semiconductor element;
a second semiconductor active region provided in a second area of the substrate adjacent to the first area;
an insulating region surrounding side surfaces of the first and second semiconductor active regions;
a mechanical electrode provided in a third area adjacent to the second area and surrounded not only by a part of the insulating region extending on the side surface of the second area but also by a trench;
a first interconnection layer one end of which is connected to the second semiconductor active region and of which the other end extends to the first semiconductor active region; and
a second interconnection layer of one end which is connected to the mechanical electrode and of which the other end extends to the one end of the first interconnection layer on the second semiconductor active region via a part of the insulating region.

7. The integrated circuit of claim 6, wherein the insulating region includes an insulating trench and an insulator embedded in the insulating trench.

8. The integrated circuit of claim 6, wherein the insulating region is a selective oxide film on the first and second semiconductor active regions.

9. The integrated circuit of claim 6, wherein the substrate is a semiconductor substrate or an insulating substrate; and the first and second semiconductor active regions are a mono-crystal semiconductor layer provided on the chip via the insulator.

10. The integrated circuit of claim 6, further comprising an MEMS provided in the third area and activated in response to a drive signal supplied to the mechanical electrode; a drive circuit generating a drive signal and a test circuit inspecting the operation of the drive circuit, both of which are provided in the first area; and an external test terminal provided in the second area, and extending from the drive circuit via the test circuit.

11. A method of manufacturing a hybrid type semiconductor integrated circuit, the method comprising:
forming an insulating region on a semiconductor layer of a substrate in accordance with a profile of a first area, and forming a semiconductor active region, the semiconductor active region being surrounded by the insulating region;
forming an interconnection layer, the interconnection layer passing over a part of the insulating region and extending from the semiconductor active region to a part of a second area adjacent to the first area of the semiconductor layer;
forming a trench, in the second area, around the semiconductor layer to which the interconnection layer is connected and a part of the insulating region; and
forming a mechanical electrode whose side surfaces are surrounded by the trench and a part of the insulating region.

12. The method of claim 11, wherein the interconnection layer is made after the insulating region is completed; and the trench is made after the completion of the interconnection layer.

13. The method of claim 11, wherein the insulating region includes an insulating trench extending along the profile of the first area of the semiconductor layer; and an insulator is buried in the insulating trench.

14. The method of claim 13, wherein the insulating trench and the trench are made by an anisotropic etching process.

15. A method of manufacturing a hybrid type semiconductor integrated circuit, the method comprising:
forming an insulating region on a semiconductor layer of a substrate in accordance with profiles of adjacent first and second areas, and forming a first semiconductor active region in the first area and a second semiconductor active region in the second area, the first and second semiconductor active regions being surrounded by the insulating region;
forming a first interconnection layer one end of which is positioned in the second semiconductor active region and of which the other end extends to the first semiconductor active region;
forming a second interconnection layer, one end of which is connected to the first interconnection layer and the other end of which extends from the second semiconductor active region, passes over a part of the insulating region, and is connected to a part of a third area adjacent to the second area of the semiconductor layer; and
forming a trench, in the second area, around the semiconductor layer to which the interconnection layer is connected and a part of the insulating region, and forming a mechanical electrode whose side surfaces are surrounded by the trench and a part of the insulating region.

16. The method of claim 15, wherein the first interconnection layer is made after completion of the insulating region, and after simultaneously forming the first and second semiconductor active regions; the second interconnection layer is made after the first interconnection layer; and the trench is made after the second interconnection layer.

17. The method of claim 16, wherein, a test probe is brought into contact with the completed first or second interconnection layer in order to check circuits formed in the first semiconductor active region.

18. The method of claim 17, wherein the substrate is removed from the second or third area where the mechanical electrode is completed.

19. The method of claim 15, wherein the insulating region includes an insulating trench formed in accordance with the profiles of the first and second areas of the semiconductor layer, and an insulator is buried in the insulating trench.

20. The method of claim 19, wherein the insulating trench and the trench are made by an anisotropic etching process.
